(19) United States
(12) Patent Application Publication
(10) Pub. No.: US 2026/0189202 A1
(43) Pub. Date: Jul. 2, 2026

(54) BALUN AND FRONT-END CIRCUIT

(71) Applicant: Murata Manufacturing Co., Ltd., Nagaokakyo-shi (JP)

(72) Inventors: Kenji Tahara, Nagaokakyo-shi (JP); Kae Yamamoto, Nagaokakyo-shi (JP)

(21) Appl. No.: 19/533,395

(22) Filed: Feb. 9, 2026

Related U.S. Application Data
(63) Continuation of application No. PCT/JP2024/030414, filed on Aug. 27, 2024.

(30) Foreign Application Priority Data
Aug. 31, 2023 (JP) 2023-140616

(51) Int. Cl. H03F 3/24

(52) U.S. Cl. CPC H03F 3/245; H03F 2200/09; H03F 2200/451

(57) ABSTRACT

A dielectric substrate, a ground electrode, an unbalanced terminal, and a pair of balanced terminals including a first balanced terminal that are provided in or on the dielectric substrate, a main line with one end connected to the unbalanced terminal and another end left open, a first sub-line with one end connected to the first balanced terminal and another end connected to the ground electrode, a first line with one end connected to the first balanced terminal and another end left open, and a second line with one end connected to the ground electrode and another end left open are included. The first sub-line is arranged between the first line and the main line and between the second line and the main line, and the other end of the first line faces the other end of the second line.

### CROSS REFERENCE TO RELATED APPLICATION

This is a continuation of International Application No. PCT/JP 2024/030414 filed on Aug. 27, 2024 which claims priority from Japanese Patent Application No. 2023-140616 filed on Aug. 31, 2023. The contents of these applications are incorporated herein by reference in their entireties.

### BACKGROUND OF THE DISCLOSURE

### Field of the Disclosure

The present disclosure relates to baluns that convert signals between unbalanced and balanced terminals and more specifically to structures for improving characteristics of baluns.

### Description of the Related Art

Baluns are known as transformers used for bidirectional conversion between unbalanced and balanced signals. A balanced signal is a pair of signals with equal amplitude and inverted phase with respect to each other. Balanced signals are used in differential amplifier circuits and antennas and are less susceptible to noise. In contrast, unbalanced signals are used in transmission systems that transmit changes in potential relative to the ground electrode. Unbalanced signals are less expensive but are more susceptible to noise than balanced signals.

Japanese Unexamined Patent Application Publication No. 2017-158174 discloses a so-called Marchand balun using coupled lines, which are obtained by coupling two lines connected to balanced terminals and having a length of ¼ of a wavelength λ to a line connected to an unbalanced terminal and having a length of ½ of the wavelength λ (λ/2).

As a transformer other than baluns that performs bidirectional conversion between unbalanced and balanced signals, there is a magnetic coupled transformer (MCT) device that uses magnetic coupling between a primary transformer and a secondary transformer. Generally, the sizes of MCT devices and Marchand baluns are determined based on the length of the wavelength λ. Since MCT devices use shorter lines than those used for Marchand baluns, the sizes of apparatuses can be made smaller than when Marchand baluns are applied. However, in the sub-terahertz band, the parasitic capacitance between the transformer wires becomes large, which degrades the characteristics.

At high frequencies such as sub-terahertz, the line length is extremely reduced. Thus, even if Marchand baluns are applied, the apparatuses can be made smaller and achieve lower loss. Thus, in recent years, the Marchand balun has attracted attention as a transformer applicable to high-frequency signals such as sub-terahertz signals.

### BRIEF SUMMARY OF THE DISCLOSURE

In addition to the sub-terahertz frequency band, the apparatus in which such a Marchand balun is installed may handle a frequency band other than the sub-terahertz band (for example, the 60 GHz to 90 GHz band). In this case, in the Marchand balun, there may be a need to pass signals in a desired sub-terahertz frequency band (passband) while blocking signals in a specific frequency band other than the sub-terahertz band (attenuation band).

By connecting a notch filter formed by connecting an inductor and a capacitor in series to the Marchand balun, the passage of signals in a certain frequency band other than the sub-terahertz band can be blocked. However, the provision of the notch filter may affect the pass characteristics of the Marchand balun. In addition, the inductor and the capacitor need to be additionally provided to configure the notch filter, which increases the number of components and may hinder the miniaturization of the apparatus.

Another possible means of blocking the passage of a certain frequency band is to use a surface acoustic wave (SAW) filter, but use of a SAW filter increases loss when passing high-frequency signals such as signals in the sub-terahertz band.

The present disclosure has been made to solve such problems. A possible benefit of the present disclosure is to improve the attenuation characteristics of stopbands of baluns used in communication devices while maintaining the pass characteristics of desired passbands.

A balun according to the present disclosure includes a dielectric substrate, a ground electrode, an unbalanced terminal, and a pair of balanced terminals including a first balanced terminal that are provided in or on the dielectric substrate, a main line with one end connected to the unbalanced terminal and another end left open, a first sub-line with one end connected to the first balanced terminal and another end connected to the ground electrode, a first line with one end connected to the first balanced terminal and another end left open, and a second line with one end connected to the ground electrode and another end left open. The other end of the first line faces the other end of the second line.

A balun according to a certain aspect is a balun in which a first frequency band is a passband and a second frequency band is an attenuation band and includes a dielectric substrate, a ground electrode, an unbalanced terminal, and a pair of balanced terminals including a first balanced terminal that are provided in or on the dielectric substrate, a main line with one end connected to the unbalanced terminal and another end left open, a first sub-line with one end connected to the first balanced terminal and another end connected to the ground electrode, a first line with one end connected to the first balanced terminal and another end left open, a second line with one end connected to the ground electrode and another end left open, and a first capacitor connected between the other end of the first line and the other end of the second line. A resonant frequency of an LC series resonator formed by the first capacitor, the first line, and the second line is a center frequency of the second frequency band, and a resonant frequency of an LC parallel resonator formed by the first capacitor and the first sub-line is a center frequency of the first frequency band.

According to the present disclosure, in addition to the first sub-line that connects to the balanced terminal, the balun includes the first line that connects to the ground electrode, and the second line that connects to the balanced terminal. The end portion of the first line and the end portion of the second line face each other, which causes capacitive coupling between the first line and the second line. For signals in a passband, the first sub-line is used as a part of a Marchand balun. For signals in a stopband, an LC series resonator formed by the first line and second line operates as a notch filter. As a result, in baluns used in communication devices, the attenuation characteristics of the stopbands can be improved while maintaining the pass characteristics of the desired passbands.

### BRIEF DESCRIPTION OF THE SEVERAL VIEWS OF THE DRAWINGS

FIG. 1 is a block diagram of a communication device equipped with a front-end circuit to which a balun according to a first embodiment is applied.

FIG. 2 is an example of a circuit diagram of the balun illustrated in FIG. 1.

FIG. 3 is a plan view of the balun according to the first embodiment.

FIG. 4 is a perspective view for describing the shapes of end portions.

FIG. 5 is a cross-sectional view for describing the shapes of the end portions.

FIG. 6 is an example of a circuit diagram of a balun according to a comparative example.

FIG. 7 is a plan view of the balun according to the comparative example.

FIG. 8 is a diagram for comparing the attenuation characteristics of the balun according to the first embodiment and those of the balun according to the comparative example.

FIG. 9 is a diagram for comparing the pass characteristics of the balun according to the first embodiment and those of the balun according to the comparative example.

FIG. 10 is a diagram for describing attenuation characteristics when the capacitance values of capacitors are changed.

FIG. 11 is a diagram for describing the pass characteristics of the balun illustrated in FIG. 10.

FIG. 12 is a cross-sectional view of a line.

FIG. 13 is a diagram for describing the electric field coupling between wiring patterns in the balun according to the comparative example.

FIG. 14 is a diagram for describing the electric field coupling between wiring patterns in the first embodiment.

FIG. 15 is a plan view of a balun according to a second embodiment.

FIG. 16 is a schematic diagram of the configuration of a communication device according to a third embodiment.

FIG. 17 is a schematic diagram of the configuration of a communication device according to a fourth embodiment.

FIG. 18 is a schematic diagram of the configuration of a communication device according to a fifth embodiment.

### DETAILED DESCRIPTION OF THE DISCLOSURE

The following is a detailed description of embodiments of the present disclosure with reference to the drawings. Note that the same or equivalent portions in the drawings are marked with the same symbols and their descriptions are not repeated.

### First Embodiment

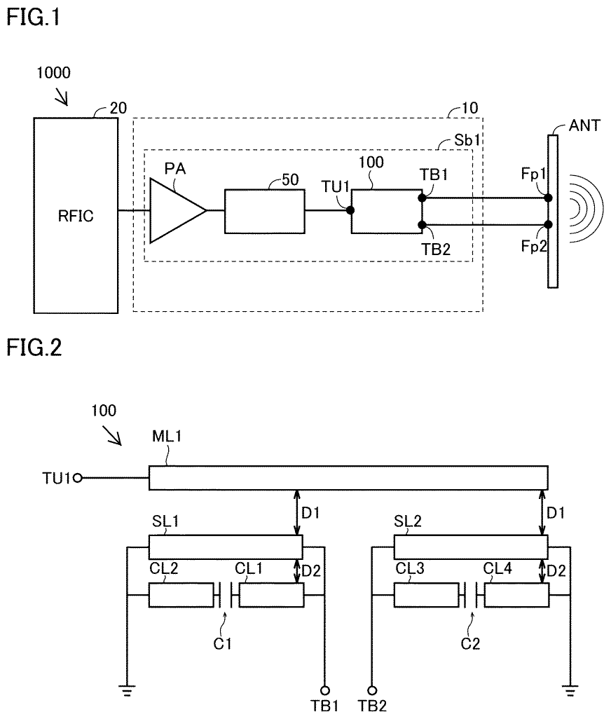

The schematic configuration of a balun 100 and a front-end circuit 10 according to a first embodiment will be described using FIG. 1.

### Overview of Communication Device

FIG. 1 is a block diagram of a communication device 1000 equipped with the front-end circuit 10 to which the balun 100 according to the first embodiment is applied. With reference to FIG. 1, the communication device 1000 includes an antenna ANT and a radio frequency integrated circuit (RFIC) 20, which is a signal processing circuit, in addition to the front-end circuit 10.

The RFIC 20 outputs, to the front-end circuit 10, radio frequency signals to be radiated from the antenna ANT. The front-end circuit 10 includes a matching circuit 50 and a power amplifier PA in addition to the balun 100. The balun 100, the matching circuit 50, and the power amplifier PA are arranged in the same dielectric substrate, which is denoted by Sb1.

The base material of the dielectric substrate Sb1 is a compound semiconductor. The compound semiconductor is fabricated by an integrated circuit process using, as a material, a semiconductor mainly composed of a compound of a group III element and a group V element, for example. The semiconductor described above is, for example, a semiconductor mainly composed of gallium arsenide (GaAs).

The power amplifier PA amplifies radio frequency signals transferred from the RFIC 20 and outputs the amplified radio frequency signals to the matching circuit 50. The matching circuit 50 is provided between the power amplifier PA and the balun 100 and achieves impedance matching between the power amplifier PA and the balun 100. The radio frequency signals matched by the matching circuit 50 are transferred to the balun 100.

The balun 100 is a transformer that converts signals between unbalanced and balanced signals. In the first embodiment, the balun 100 converts unbalanced signals to balanced signals. A balanced signal is a pair of signals with equal amplitude and inverted phase with respect to each other. Unbalanced signals are used in transmission systems that transmit changes in potential with respect to the ground electrode. A radio frequency signal obtained by the balun 100 converting from an unbalanced signal to a balanced signal is transferred to the antenna ANT. The antenna ANT is, for example, a patch antenna having feed points Fp1 and Fp2.

The balun 100 has an unbalanced terminal TU1 and two balanced terminals (a balanced terminal TB1, a balanced terminal TB2). The balanced signal converted by the balun 100 and outputted from the balanced terminal TB1 is supplied to the feed point Fp1 of the antenna ANT. The balanced signal outputted from the balanced terminal TB2 is supplied to the feed point Fp2 of the antenna ANT. The feed points Fp1 and Fp2 are offset from the center of the radiating electrode in the antenna ANT, which is a patch antenna, in opposite directions to each other in the polarization direction. For the same polarization direction, the balun 100 feeds two signals with inverted phase to the antenna ANT.

### Cconfiguration of Balun

FIG. 2 is an example of a circuit diagram of the balun 100 illustrated in FIG. 1. The balun 100 is a so-called Marchand balun, in which two sub-lines SL1 and SL2 having a length of ¼ of a wavelength λ are coupled to a main line ML1 connected to the unbalanced terminal and having a length of ½ of the wavelength λ (λ/2). In this manner, in the Marchand balun, the lengths of the main line ML1 and sub-lines SL1 and SL2 are set appropriately based on the wavelength λ of a radio frequency signal to be passed.

With reference to FIG. 2, the balun 100 includes lines CL1 to CL4 in addition to the unbalanced terminal TU1, the balanced terminals TB1 and TB2, the main line ML1, and the sub-lines SL1 and SL2. As described above, in a case where the wavelength of the radio frequency signal to be passed is λ, the main line ML1 has an electrical length of λ/2. Each of the sub-line SL1 and the sub-line SL2 has an electrical length of λ/4. In contrast, each of the lines CL1 to CL4 has an electrical length of λ/8.

In the first embodiment, an example will be described in which the balun 100 converts an unbalanced signal to a balanced signal. In the balun 100, the unbalanced terminal TU1 is an input terminal, and the balanced terminals TB1 and TB2 are output terminals. Note that the balun 100 can also be used when balanced signals inputted to the balanced terminal TB1 and the balanced terminal TB2 are converted to unbalanced signals, and the unbalanced signals are outputted from the unbalanced terminal TU1.

The passband of the balun 100 according to the first embodiment is the band from 120 GHz to 140 GHz. Note that, in a certain aspect, the passband of the balun 100 may be any other band. For example, the passband may be the band from 130 GHz to 150 GHz or the band from 140 GHz to 160 GHz.

The balun 100 according to the first embodiment has a stopband that attenuates signals in a specific band. In the example of the first embodiment, the stopband (attenuation band) is the band from 60 GHz to 90 GHz. Note that, in a certain aspect, the stopband of the balun 100 may be any other band. For example, the stopband may be the band from 50 GHz to 80 GHz or the band from 70 GHz to 100 GHz.

As illustrated in FIG. 2, one end of the main line ML1 is connected to the unbalanced terminal TU1, and the other end is left open. The sub-line SL1 is connected between the balanced terminal TB1 and the ground electrode (reference potential). The sub-line SL1 is arranged to be electromagnetically coupled to the main line ML1. Similarly, the sub-line SL2 is connected between the balanced terminal TB2 and the ground electrode. The sub-line SL2 is arranged to be electromagnetically coupled to the main line ML1.

The sub-lines SL1 and SL2 are connected to the ground electrode and the balanced terminals TB1 and TB2 so that the phase of the radio frequency signal outputted via the sub-line SL1 is inverted with respect to that of the radio frequency signal outputted via the sub-line SL2. In a Marchand balun with such a configuration, radio frequency signals inputted to the unbalanced terminal TU1 (input terminal) are transferred to the two balanced terminals via electromagnetic coupling and outputted as balanced signals from the balanced terminal TB1 (output terminal) and balanced terminal TB2 (output terminal).

As illustrated in FIG. 2, the line CL1, a capacitor C1, and the line CL2 are connected in series between the balanced terminal TB1 and the ground electrode in this order. The inductance components of the lines CL1 and CL2 and the capacitor C1 constitute an LC series resonator. As illustrated in FIG. 2, the line CL1, the capacitor C1, and the line CL2 that are connected in series are connected in parallel to the sub-line SL1 between the balanced terminal TB1 and the ground electrode. The inductance component of the sub-line SL1, and the capacitor C1 constitute an LC parallel resonator.

Similarly, the line CL3, a capacitor C2, and the line CL4 are connected in series between the balanced terminal TB2 and the ground electrode in this order. The inductance components of the lines CL3 and CL4 and the capacitor C2 constitute an LC series resonator. As illustrated in FIG. 2, the line CL3, the capacitor C2, and the line CL4 are connected in parallel to the sub-line SL2 between the balanced terminal TB2 and the ground electrode. The inductance component of the sub-line SL2, and the capacitor C2 constitute an LC parallel resonator.

As illustrated in FIG. 2, each of the distance between the sub-line SL2 and the main line ML1 and the distance between the sub-line SL1 and the main line ML1 is a distance D1. Each of the distance between the sub-line SL2 and the line CL4 and the distance between the sub-line SL2 and the line CL3 is a distance D2. Each of the distance between the sub-line SL1 and the line CL1 and the distance between the sub-line SL1 and the line CL2 is also the distance D2.

In the balun 100 according to the first embodiment, the provision of the lines CL1 to CL4 and capacitors C1 and C2 illustrated in FIG. 2 improves the attenuation characteristics of the stopband while maintaining the pass characteristics of the passband. Note that the main line ML1 may correspond to a “main line” in the present disclosure. Moreover, the sub-line SL1 and sub-line SL2 may correspond to a “first sub-line” and a “second sub-line” in the present disclosure, respectively. Furthermore, the lines CL to CL4 may correspond, respectively, to a “first line” to a “fourth line” in the present disclosure.

Furthermore, the balanced terminal TB1 may correspond to a “first balanced terminal” in the present disclosure. The balanced terminal TB2 may correspond to a “second balanced terminal” in the present disclosure. The passband (120 GHz to 140 GHz in the first embodiment) may correspond to a “first frequency band” in the present disclosure. The stopband (60 GHz to 90 GHz in the first embodiment) may correspond to a “second frequency band” in the present disclosure.

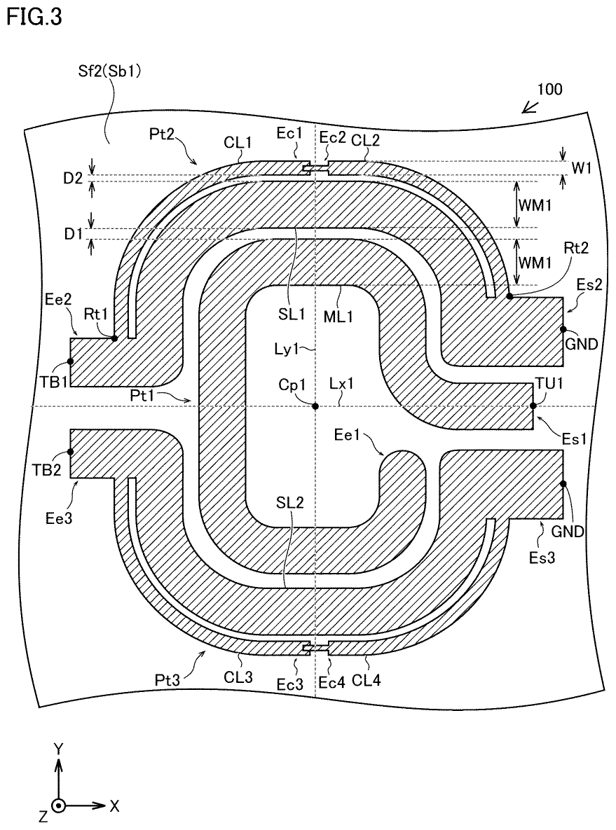

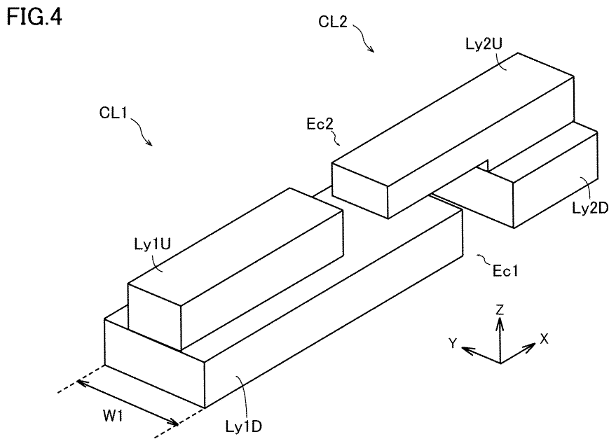

Next, the shape of the balun 100 illustrated in FIG. 2 will be described in detail using FIGS. 3 to 5. FIG. 3 is a plan view of the balun 100 according to the first embodiment. FIG. 3 illustrates the balun 100, which is formed on a main surface Sf2 of the dielectric substrate Sb1. In FIGS. 3 to 5, the direction normal to the main surface Sf2 is the Z-axis, a certain direction in the main surface Sf2 is the X-axis, and the direction orthogonal to the X-axis is the Y-axis. That is, FIG. 3 illustrates the main surface Sf2 of the dielectric substrate Sb1 viewed from the positive Z-axis direction. In the first embodiment, the dielectric substrate Sb1 is a multilayer substrate in which multiple layers are stacked in the Z-axis direction. That is, the Z-axis direction is the stacking direction of the dielectric substrate Sb1. Note that, in a certain aspect, the dielectric substrate Sb1 may be a single-layer substrate.

The main line ML1, the sub-lines SL1 and SL2, and the lines CL1 to CL4 included in the balun 100 are formed on the main surface Sf2 of the dielectric substrate Sb1. A point Cp1 is a point within the main surface Sf2. The main line ML1, the sub-lines SL1 and SL2, and the lines CL1 to CL4 are arranged around the point Cp1. The balun 100 includes a wiring pattern Pt1, a wiring pattern Pt2, and a wiring pattern Pt3.

First, the wiring pattern Pt1 will be described. The main line ML1 described with reference to FIG. 2 is realized by the wiring pattern Pt1 illustrated in FIG. 3. The wiring pattern Pt1 is a wiring pattern including an end portion Es1 and an end portion Ee1. The wiring pattern Pt1 is connected to the unbalanced terminal TU1 at the end portion Es1. As illustrated in FIG. 3, the main line ML1 extends from the end portion toward the negative X-axis direction side and then winds counterclockwise around the Z-axis passing through the point Cp1 as the winding axis.

In other words, the main line ML1 has a shape wound around the Z axis passing through the point Cp1 when the dielectric substrate Sb1 is viewed in plan view. This allows the balun 100 to be smaller than when the main line ML1 is straight without winding. The end portion Ee1 is an open end. Among the wiring patterns Pt1 to Pt3, the wiring pattern Pt1 is arranged at the closest position to the point Cp1. In other words, the wiring pattern Pt1 is arranged at the innermost side of the balun 100.

Subsequently, the wiring patterns Pt2 and Pt3 will be described. The wiring pattern Pt2 is arranged on the positive Y-axis direction side with respect to the wiring pattern Pt1. Each of the sub-line SL1 and the lines CL1 and CL2 described with reference to FIG. 2 is realized by the wiring pattern Pt2 illustrated in FIG. 3. The wiring pattern Pt2 has an end portion Es2 and an end portion Ee2.

The wiring pattern Pt3 is arranged on the negative Y-axis direction side with respect to the wiring pattern Pt1. Each of the sub-line SL2 and the lines CL3 and CL4 described with reference to FIG. 2 is realized by the wiring pattern Pt3 illustrated in FIG. 3. The wiring pattern Pt3 has an end portion Es3 and an end portion Ee3.

In the balun 100, the wiring pattern Pt1 is arranged between the wiring pattern Pt2 and the wiring pattern Pt3. The wiring pattern Pt2 and the wiring pattern Pt3 have shapes that are line-symmetric with respect to a line Lx1 illustrated in FIG. 3 as a center line. The line Lx1 is a line that passes through the point Cp1 in the X-axis direction. A line Ly1 is a line that passes through the point Cp1 in the Y-axis direction.

The wiring pattern Pt2 is connected to a ground electrode GND at the end portion Es2. As illustrated in FIG. 3, the sub-line SL1 is arranged along the main line ML1 arranged on the positive Y-axis direction side with respect to the line Lx1. In other words, the sub-line SL1 is substantially U-shaped. In other words, the sub-line SL1 has a shape similar to a semicircular arc. The sub-line SL1 electromagnetically couples to the main line ML1 arranged on the positive Y-axis direction side with respect to the line Lx1. The distance between the sub-line SL1 and the main line ML1 is the distance D1.

The distance D1 is, as an example, greater than or equal to 5 μm and less than 6 μm in length. As illustrated in FIG. 3, the distance D1 is illustrated as the distance between the sub-line SL1 and the main line ML1 in the Y-axis direction; however, the distance between the sub-line SL1 and the main line ML1 is also the distance D1 in the X-axis direction and at curved portions. That is, the sub-line SL1 and the main line ML1 are arranged so that the distance between the sub-line SL1 and the main line ML1 in each direction is uniformly the distance D1. In other words, the distance D1 is the shortest distance between the end of a side surface of the sub-line SL1 to the end of a side surface of the main line ML1.

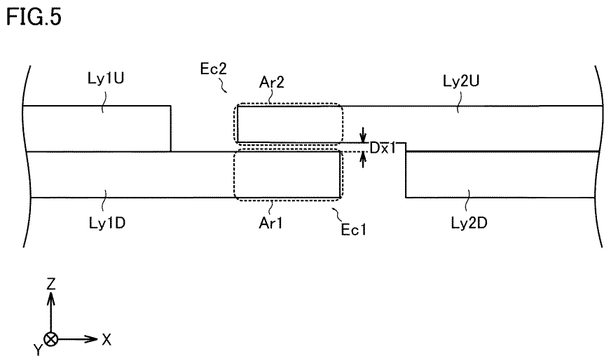

The line CL1 has the end portion Ee2, which is shared with the sub-line SL1, and an end portion Ec1. As illustrated in FIG. 3, the line CL1 is a line extending toward the positive Y-axis direction side from a point Rt1 at the end portion Ee2, while bending toward the positive X-axis direction side. The line CL1 is connected to the balanced terminal TB1 at the end portion Ee2. The end portion Ec1 is an open end. The shape of the end portion Ec1 will be described in detail using FIGS. 4 and 5 below.

The line CL1 is arranged along the sub-line SL1 arranged on the negative X-axis direction side with respect to the line Ly1. That is, the line CL1 has a shape similar to a quarter-circle arc. The distance between the line CL1 and the sub-line SL1 is the distance D2. The distance D2 is, as an example, greater than or equal to 3 μm and less than 5 μm in length.

The distance between the line CL1 and the sub-line SL1 is also the distance D2 in the Y-axis direction as well as in the X-axis direction and at curved portions. That is, the line CL1 and the sub-line SL1 are arranged so that the distance between the line CL1 and the sub-line SL1 in each direction is uniformly the distance D2. In other words, the distance D2 is the shortest distance between the end of a side surface of the line CL1 to the end of the side surface of the sub-line SL1.

The line CL2 has the end portion Es2, which is shared with the sub-line SL1, and an end portion Ec2. As illustrated in FIG. 3, the line CL2 is a line extending toward the positive Y-axis direction side from a point Rt2 at the end portion Es2, while bending toward the negative X-axis direction side. The line CL2 is connected to the ground electrode GND at the end portion Es2. The end portion Ec2 is an open end. The shape of the end portion Ec2 will be described in detail using FIGS. 4 and 5 below.

The line CL2 is arranged along the sub-line SL1 arranged on the positive X-axis direction side with respect to the line Ly1. The line CL2 has a shape similar to a quarter-circle arc. Similar to the distance between the line CL1 and the sub-line SL1, the distance between the line CL2 and the sub-line SL1 is the distance D2. That is, the line CL2 and the sub-line SL1 are arranged so that the distance between the line CL2 and the sub-line SL1 in each direction is uniformly the distance D2. In other words, the distance D2 is the shortest distance between the end of a side surface of the line CL2 to the end of the side surface of the sub-line SL1.

In this manner, the sub-line SL1 is arranged along the main line ML1, and furthermore, the lines CL1 and CL2 are arranged along the part of the sub-line SL1. As a result, the sub-line SL1 is arranged between the line CL1 and line CL2 and the main line ML1. Since the sub-line SL1 is arranged between the main line ML1 and the lines CL1 and CL2, the degree of coupling between the lines CL1 and CL2 and the main line ML1 is weaker than that between the sub-line SL1 and the main line ML1.

The wiring pattern Pt2 is formed so that the distance D2 is shorter than the distance D1. The wiring pattern Pt2 is connected to the balanced terminal TB1 at the end portion Ee2. This allows the total electrical length, which is obtained by adding the electrical length of the line CL1 and that of the line CL2, to be closer to the electrical length of the sub-line SL1. Since the lines CL1 and CL2 are arranged on the outer side with respect to the sub-line SL1, the greater the distance D2, the longer the electrical lengths of the lines CL1 and CL2. Thus, the difference between the total electrical length of the lines CL1 and CL2 and the electrical length of the sub-line SL1 becomes larger.

In the first embodiment, the distance D2 is shorter than the distance D1 to reduce the difference between the electrical length of the sub-line SL1 and the total electrical length of the lines CL1 and CL2. This can prevent the electrical length of the sub-line SL1 from deviating from a length of λ/4 and also prevent the length of each of the lines CL1 and CL2 from deviating from a length of λ/8.

In the balun 100 illustrated in FIG. 3, the length of the line CL1 in its extending direction is the same as that of the line CL2 in its extending direction. Specifically, the length of the line CL1 extending from the point Rt1 to the tip of the end portion Ec1 is the same as that of the line CL2 extending from the point Rt2 to the tip of end portion Ec2. As a result, the magnitude of the inductance component of the line CL1 is substantially the same as that of the line CL2, which facilitates the design of the LC series resonator formed by the lines CL1 and CL2 and the capacitor C1 described with reference to FIG. 2. Note that, in a certain aspect, the length of the line CL1 in its extending direction may be different from that of the line CL2 in its extending direction.

The wiring pattern Pt3 and the wiring pattern Pt2 have shapes that are line-symmetric with respect to the line Lx1 as the center line. Similar to the wiring pattern Pt2, the distance between the sub-line SL2 and the main line ML1 is the distance D1.

The line CL3 is arranged along the sub-line SL2 arranged on the negative X-axis direction side with respect to the line Ly1. The distance between the line CL3 and the sub-line SL2 is the distance D2. The line CL3 is connected to the balanced terminal TB2 at the end portion Ee3. The end portion Ec3 is an open end. The line CL4 is arranged along the sub-line SL2 arranged on the positive X-axis direction side with respect to the line Ly1. The distance between the line CL4 and the sub-line SL2 is the distance D2. The line CL4 is connected to the ground electrode GND at the end portion Es3. The end portion Ec4 is an open end.

The width of the main line ML1 is a width WM1 in length. Similar to the main line ML1, the width of the sub-line SL1 is the width WM1 in length. Although not illustrated, the width of the sub-line SL2 is also the width WM1 in length. In contrast, the width of each of the lines CL1 and CL2 is a width W1 in length. Although not illustrated, each of the lines CL3 and CL4 is also the width W1 in length. Note that width means the length of a line in the direction orthogonal to the line's extension direction.

### Shapes of End Portions Ec1 and Ec2 of Lines CL1 and CL2

FIG. 4 is a perspective view for describing the shapes of the end portions Ec1 and Ec2. The shapes of the end portions Ec3 and Ec4 in FIG. 3 are substantially the same as those of the end portions Ec1 and Ec2. Thus, for ease of explanation hereafter, the end portions Ec1 and Ec2 will be used as an example.

As illustrated in FIG. 4, the line CL1 is composed of two stacked electrode layers, a layer Ly1U and a layer Ly1D. The layer Ly1U is arranged on the positive Z-axis direction side with respect to the layer Ly1D. The width of the layer Ly1U is smaller than the width W1. The line CL1 has a shape in which the end portion of the layer Ly1D protrudes further toward the positive X-axis direction side than that of the layer Ly1U does.

In contrast, the line CL2 is composed of two stacked electrode layers, a layer Ly2U and a layer Ly2D. The layer Ly2U is arranged on the positive Z-axis direction side with respect to the layer Ly2D. The width of the layer Ly2U is smaller than the width W1 and is the same as that of the layer Ly1U. Unlike the line CL1, the line CL2 has a shape in which the end portion of the layer Ly2U protrudes further toward the negative X-axis direction side than that of the layer Ly2D does.

FIG. 5 is a cross-sectional view for describing the shapes of the end portions Ec1 and Ec2. FIG. 5 illustrates a view of the end portions Ec1 and Ec2 seen from the negative Y-axis direction side. As illustrated in FIG. 5, only a portion of the positive Z-axis direction side of the layer Ly2U protrudes from the layer Ly2D toward the negative X-axis direction side.

This means that the end portion Ec2 of the line CL2 and the end portion Ec1 of the line CL1 are not in direct contact with each other and are arranged so as to be away from each other by a distance Dx1. A region Ar1 of the end portion Ec1 of the line CL1 faces a region Ar2 of the end portion Ec2 of the line CL2 in the Z-axis direction. That is, the end portion Ec1 of the line CL1 and the end portion Ec2 of the line CL2 face each other. Within this distance Dx1, the capacitor C1 described with reference to FIG. 2 is formed.

In the above-described example, the capacitor c1 is formed when the region Ar1 and the region Ar2 face each other in the Z-axis direction; however, the lines CL1 and CL2 may have other structures to form the capacitor C1. For example, in a certain aspect, a layer of the line CL1 and a layer of the line CL2 that are arranged on the same layer may be brought closer to face each other in the X-axis, so that the capacitor C1 may be formed. That is, it is sufficient that the capacitor C1 be formed when the end portion Ec1 and the end portion Ec2 face each other. The direction in which the end portion Ec1 and the end portion Ec2 face each other may be the stacking direction or the in-plane direction of the main surface Sf2, which is orthogonal to the stacking direction. To increase the capacitance value of the capacitor C1, the shapes of the end portions Ec1 and Ec2 may be deformed so that the facing area increases. In the balun 100 according to the first embodiment, the capacitor C2 is formed by the lines CL3 and CL4 having substantially the same shapes as those described with reference to FIGS. 4 and 5.

### Comparative Example

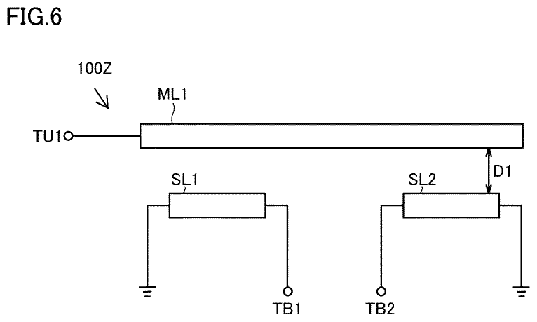

FIG. 6 is an example of a circuit diagram of a balun 100Z according to a comparative example. The balun 100Z in FIG. 6 is a typical Marchand balun and has a configuration obtained by removing the lines CL1 to CL4 from the balun 100 according to the first embodiment.

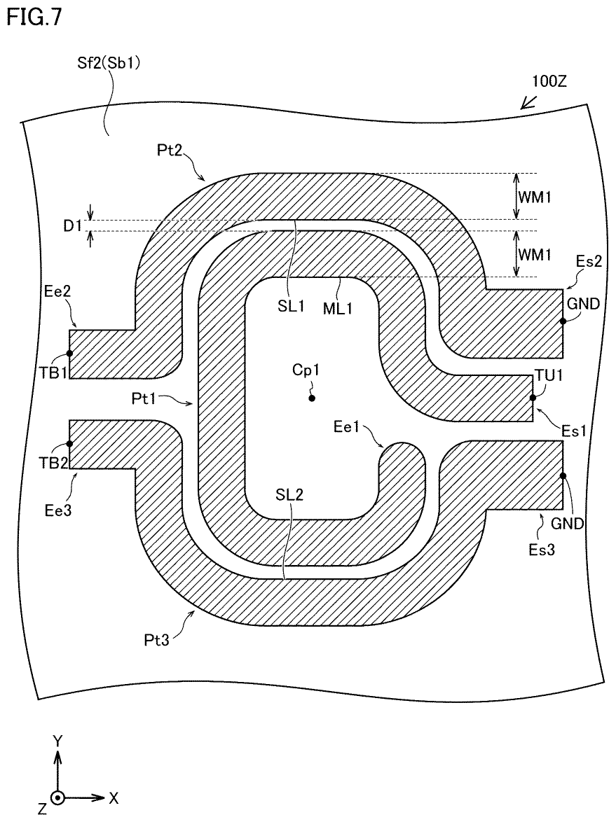

FIG. 7 is a plan view of the balun 100Z according to the comparative example. As illustrated in FIG. 7, wiring patterns Pt2 and Pt3 according to the comparative example have shapes obtained by removing the lines CL1 to CL4 from the wiring patterns Pt2 and Pt3 according to the first embodiment. That is, the wiring patterns Pt2 and Pt3 in the balun 100Z according to the comparative example have only the sub-lines SL1 and SL2, respectively.

### Comparison of Attenuation and Pass Characteristics

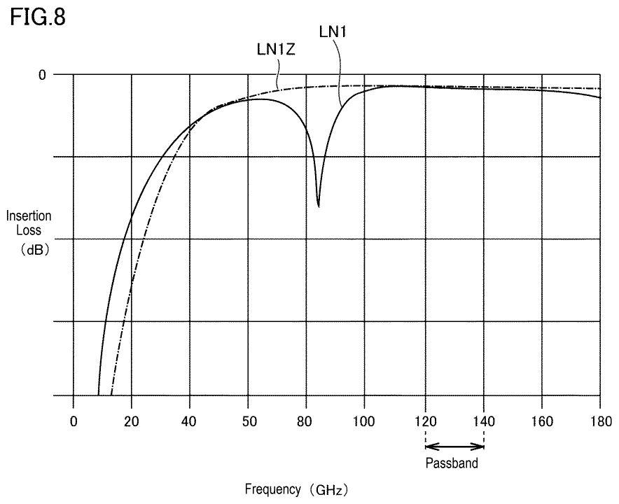

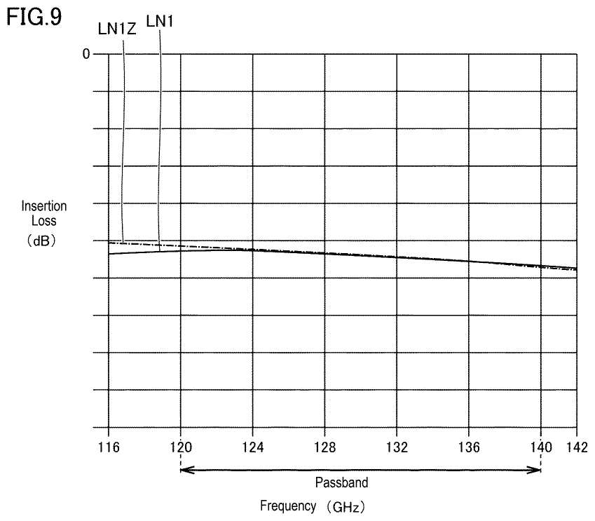

FIG. 8 is a diagram for comparing the attenuation characteristics of the balun 100 according to the first embodiment with those of the balun 100Z according to the comparative example. FIG. 9 is a diagram for comparing the pass characteristics of the balun 100 according to the first embodiment with those of the balun 100Z according to the comparative example. FIG. 9 illustrates an enlarged view of insertion loss near the passband of FIG. 8. In FIGS. 8 and 9, the horizontal axis represents frequency, and the vertical axis represents the insertion loss of the baluns 100 and 100Z.

In FIGS. 8 and 9, a line LN1 indicates the insertion loss of the balun 100 according to the first embodiment (FIGS. 2 to 5). The line LN1 is a solid line. A line LN1Z indicates the insertion loss of the balun 100Z according to the comparative example (FIGS. 6 and 7). The line LN1Z is a dot-and-dash line.

The capacitance value of the capacitor C1 of the balun 100 according to the first embodiment indicated by the line LN1 is adjusted so that the resonant frequency of the LC series resonator described with reference to FIG. 2 and formed by the capacitor C1 and the lines CL1 and CL2 becomes 83.5 GHz. Similar to the capacitor C1, the capacitance value of the capacitor C2 of the balun 100 indicated by the line LN1 is also adjusted so that the resonant frequency of the LC series resonator described with reference to FIG. 2 and formed by the capacitor C2 and the lines CL3 and CL4 becomes 83.5 GHz.

As a result, when signals with the same frequency as the resonant frequency of the LC series resonators propagate through the balun 100, the signals flow through the LC series resonators to the ground electrode and are not transferred to the output terminal. That is, the LC series resonator formed by the capacitor C2 and the lines CL3 and CL4 serves as a notch filter, and an attenuation pole appears at 83.5 GHz as illustrated in FIG. 8.

In the first embodiment, the provision of the lines CL1 and CL2 and the capacitor C1 forms an LC series resonator and enables attenuation of signals in the band with the resonant frequency of the LC series resonator as its center frequency. As illustrated as the line LN1Z in FIG. 8, in the balun 100Z according to the comparative example, the attenuation in the attenuation band, 60 GHz to 90 GHz, is smaller than that in the first embodiment.

In this manner, the balun 100 according to the first embodiment can improve the attenuation characteristics of a specific frequency band more significantly than the balun 100 according to the comparative example. In contrast, as illustrated in FIG. 9, there is no significant difference in pass characteristics between the balun 100Z according to the comparative example and the balun 100 according to the first embodiment. In the balun 100 according to the first embodiment, the resonant frequency of the LC parallel resonator formed by the capacitor C1 and the sub-line SL1 as described with reference to FIG. 2 is adjusted to 130 GHz. Similarly, the resonant frequency of the LC parallel resonator formed by the capacitor C2 and the sub-line SL2 is adjusted to 130 GHz.

In the balun 100 according to the first embodiment, this prevents the LC series resonator described above from functioning as a notch filter when signals in the passband propagate through the balun 100 because the impedance of the balanced terminal TB1 is open due to the resonance of the LC parallel resonator. That is, in the balun 100 according to the first embodiment, the attenuation of signals in the passband can be suppressed even in a case where the Q value of the LC series resonant circuit is small and the attenuation band for the attenuation performed by the LC series resonant circuit is wide.

In this manner, in the balun 100 according to the first embodiment, the attenuation characteristics of the stopband can be improved while maintaining the pass characteristics of the desired passband. In addition, in the first embodiment, the LC series resonator and LC parallel resonator are realized using the sub-line SL1, which functions as a sub-line in the Marchand balun. This can suppress the increase in the number of components used to configure the balun 100 according to the first embodiment.

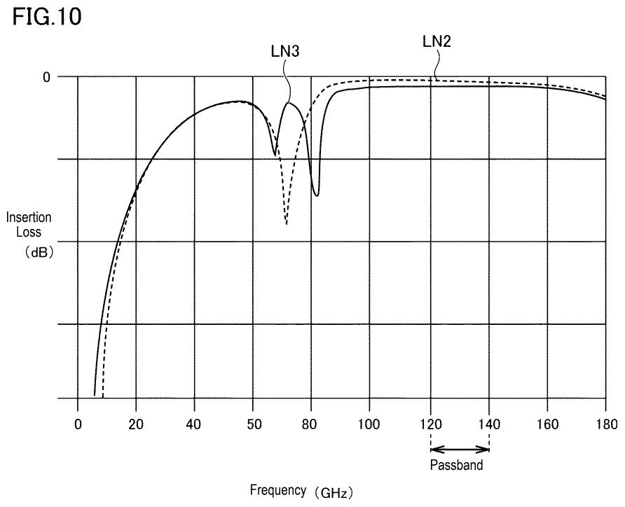

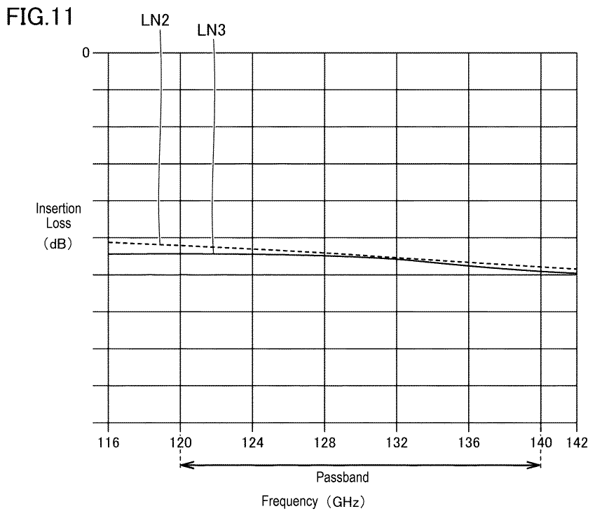

FIG. 10 is a diagram for describing the attenuation characteristics when the capacitance values of the capacitors C1 and C2 are changed. FIG. 11 is a diagram for describing the pass characteristics of the balun 100 illustrated in FIG. 10. FIG. 10 illustrates, using lines LN2 and LN3, the insertion loss when the capacitance values of the capacitors C1 and C2 of the balun 100, which exhibits the characteristics of the line LN1, are changed. The line LN2 is a broken line. The line LN3 is a solid line.

The capacitance value of the capacitor C1 of the balun 100 indicated by the line LN2 is adjusted so that the resonant frequency of the LC series resonator formed by the capacitor C1 and the lines CL1 and CL2 becomes 73.5 GHz. The capacitance value of the capacitor C2 of the balun 100 indicated by the line LN2 is adjusted so that the resonant frequency of the LC series resonator formed by the capacitor C2 and the lines CL3 and CL4 becomes 73.5 GHz. This enables an attenuation pole to appear near 73.5 GHz even in the balun 100 indicated by the line LN2.

Furthermore, the capacitance value of the capacitor C1 of the balun 100 indicated by the line LN3 is adjusted so that the resonant frequency of the LC series resonator formed by the capacitor C1 and the lines CL1 and CL2 becomes 73.5 GHz. In contrast, the capacitance value of the capacitor C2 of the balun 100 indicated by the line LN3 is adjusted so that the resonant frequency of the LC series resonator formed by the capacitor C2 and the lines CL3 and CL4 becomes 83.5 GHz. As a result, the balun 100 indicated by the line LN3 attenuates two bands: the 71 GHz to 76 GHz band and the 81 GHz to 86 GHz band. That is, the attenuation characteristics indicated by the line LN3 exhibit two attenuation poles near 73.5 GHz and 83.5 GHz. As illustrated in FIG. 11, the balun 100 indicated by the lines LN2 and LN3 also does not exhibit a significant difference in pass characteristics compared with the balun 100Z indicated by the line LN1Z.

### Coupling Coefficient of Electric Field Coupling

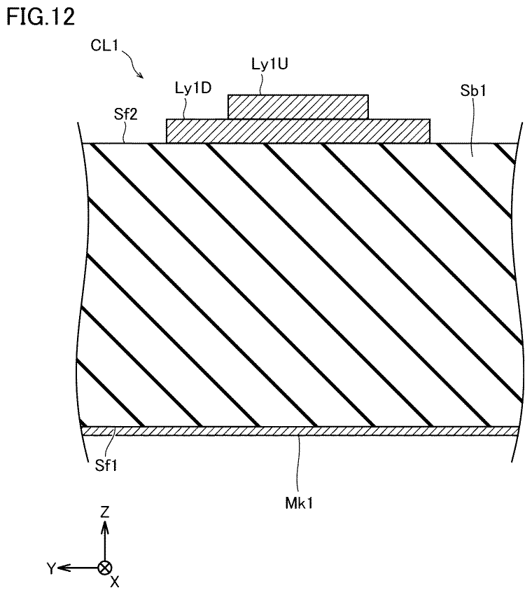

In the following, the electric field coupling between the wiring patterns Pt1 and Pt2 will be described. FIG. 12 is a cross-sectional view of the line CL1. FIG. 12 illustrates a cross-sectional view of the line CL1 seen from the negative X-axis direction side. In the balun 100 according to the first embodiment, a ground electrode Mk1 is arranged on a main surface Sf1, which is the back side of the dielectric substrate Sb1 relative to the main surface Sf2. The ground electrode Mk1 is formed by a plating process, for example. The ground electrode Mk1 is arranged on the entire main surface Sf1 and is also arranged on the negative Z-axis direction side of the main line ML1, sub-lines SL1 and SL2, and lines CL2 to CL4, which are not illustrated in FIG. 12.

In other words, each of the main line ML1, sub-lines SL1 and SL2, and lines CL1 to CL4 overlaps the ground electrode Mk1 when the main surface Sf1 is viewed in plan view. That is, capacitive coupling occurs between the main line ML1 and the ground electrode Mk1. Moreover, capacitive coupling occurs between the sub-line SL1 and the ground electrode Mk1 and between the sub-line SL2 and the ground electrode Mk1. Furthermore, capacitive coupling occurs between each of the lines CL1 to CL4 and the ground electrode Mk1.

The magnitudes of these capacitive couplings increase with the widths of the main line ML1, sub-lines SL1 and SL2, and lines CL1 to CL4 illustrated in FIG. 3. That is, in the example in FIG. 3, since the width W1 is narrower than the width WM1, the magnitudes of the capacitance components between the lines CL1 to CL4 and the ground electrode Mk1 are smaller than those between each of the main line ML1 and sub-lines SL1 and SL2 and the ground electrode Mk1.

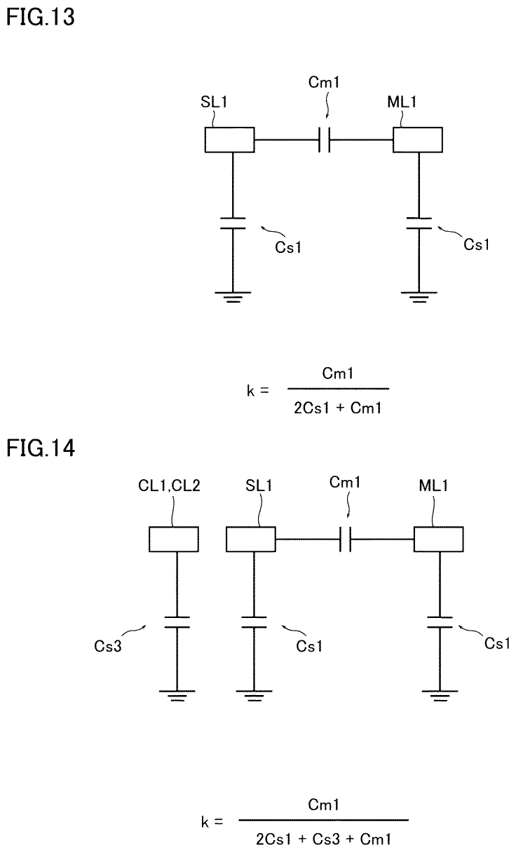

FIG. 13 is a diagram for describing the electric field coupling between the wiring patterns Pt1 and Pt2 in the balun 100Z according to the comparative example. The wiring pattern Pt1 and wiring pattern Pt2 described above are coupled to each other by the electric field. As illustrated in FIG. 13, a coupling coefficient k of the electric field coupling between the wiring patterns is generally defined by line capacitances Cs1 of the main line ML1 and sub-line SL1 and an inter-line capacitance Cm1 between the main line ML1 and the sub-line SL1.

The inter-line capacitance Cm1 is the capacitance component between the sub-line SL1 and the main line ML1. In the comparative example described above, both the width of the main line ML1 and that of the sub-line SL1 are the width WM1. Thus, both the line capacitance of the main line ML1 and that of the sub-line SL1 are the line capacitance Cs1. The line capacitance of the main line ML1 is the capacitance component between the main line ML1 and the ground electrode Mk1. The line capacitance of the sub-line SL1 is the capacitance component between the sub-line SL1 and the ground electrode Mk1.

As illustrated in FIG. 13, the coupling coefficient k between the wiring pattern Pt1 and the wiring pattern Pt2 in the balun 100Z in the comparative example is the value obtained by dividing the inter-line capacitance Cm1 between the sub-line SL1 and the main line ML1 by the sum of the inter-line capacitance Cm1 and the two line capacitances Cs1.

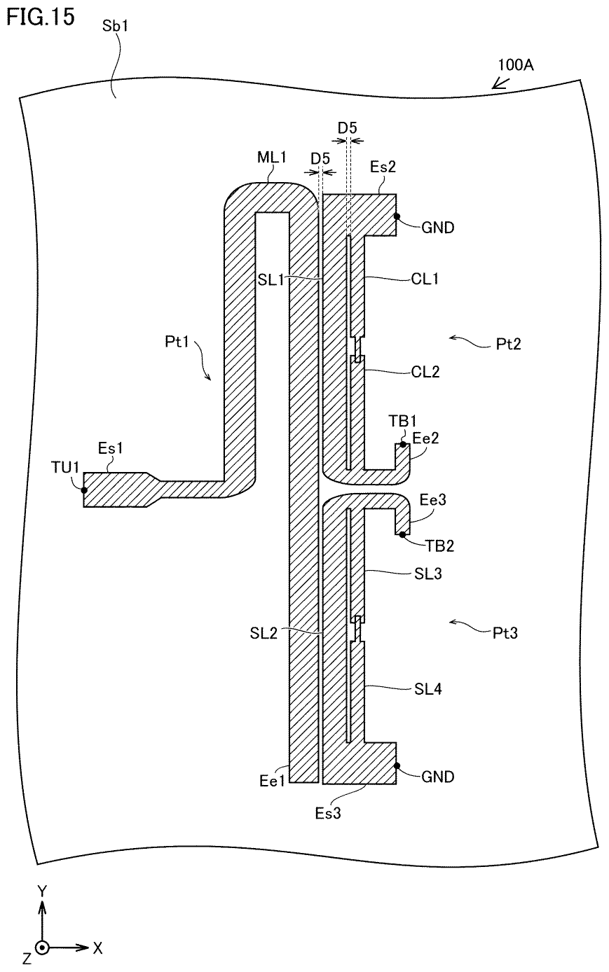

Subsequently, the electric field coupling in the first embodiment will be described. FIG. 14 is a diagram for describing the electric field coupling between the wiring patterns in the first embodiment. In the balun 100 according to the first embodiment, the lines CL1 and CL2 are provided. A line capacitance Cs3 is the capacitance component between each of the lines CL1 and CL2 and the ground electrode Mk1. The coupling coefficient k between the wiring pattern Pt1 and the wiring pattern Pt2 is the value obtained by dividing the inter-line capacitance Cm1 between the sub-line SL1 and the main line ML1 by the sum of the inter-line capacitance Cm1, the two line capacitances Cs1, and the line capacitance Cs3.

As described above, the width W1 of the lines CL1 and CL2 is smaller than the width WM1 of the main line ML1 and sub-line SL1 in the first embodiment. Thus, the line capacitance Cs3 in FIG. 14 has a smaller value than the line capacitance Cs1. As illustrated in FIG. 14, when the value of the line capacitance Cs3 is smaller, the value of the coupling coefficient k increases compared with the case where the value of the line capacitance Cs3 is larger. In the balun 100 according to the first embodiment, the width W1 is smaller than the width WM1, thereby suppressing an increase in the value of the line capacitance Cs3 and increasing the coupling coefficient k. This enables improvement of the pass characteristics of the balun 100 while suppressing a decrease in the coupling coefficient k in the first embodiment.

Note that, in the above-described example, the wiring patterns Pt1 to Pt3 arranged in the same layer on the dielectric substrate Sb1 are described as an example. However, this is not the only case, and each of the wiring patterns Pt1 to Pt3 may be provided in a different layer within the dielectric substrate Sb1, which is a multilayer substrate. That is, in the first embodiment, it is sufficient that the capacitor C1 be formed by the end portion Ec1 and the end portion Ec2 facing each other. The layers in which the main line ML1, the sub-lines SL1 and SL2, the lines CL1 to CL4, the ground electrode Mk1, the balanced terminals TB1 and TB2, and the unbalanced terminal TU1 are formed may be different layers from each other.

More specifically, if the dielectric substrate Sb1 is formed by stacking four layers (a first layer, a second layer, a third layer, and a fourth layer), the ground electrode Mk1 may be formed in the first layer, the main line ML1 in the second layer, the sub-lines SL1 and SL2 in the third layer, and the lines CL1 to CL4 in the fourth layer. Even in this case, since the sub-line SL1 is formed between the main line ML1 and the lines CL1 and CL2, the degree of coupling between the lines CL1 and CL2 and the main line ML1 is weaker than that between the sub-line SL1 and the main line ML1.

### Second Embodiment

The configuration of a balun 100A according to a second embodiment will be described using FIG. 15. FIG. 15 is a plan view of the balun 100A according to the second embodiment. In a third embodiment, the description of substantially the same configuration as that of the first embodiment will not be repeated.

In the second embodiment, a main line ML1 has a straight line shape as illustrated in FIG. 15. Sub-lines SL1 and SL2 are arranged along the main line ML1 and thus have straight line shapes, similar to the main line ML1. Even with such a shape, the provision of lines CL1 to CL4 enables the balun 100A according to the second embodiment to improve the attenuation characteristics of the stopband while maintaining the pass characteristics of the desired passband.

Furthermore, the sub-lines SL1 and SL2 and the lines CL1 and CL2 have straight line shapes in the second embodiment, and thus the distance between the sub-line SL1 and the lines CL1 and CL2 does not need to be shorter than that between the main line ML1 and the sub-line SL1. Thus, as illustrated in FIG. 15, the distances between each of the lines CL1 and CL2 and the sub-line SL1 are the same as that between the main line ML1 and the sub-line SL1 in the second embodiment, which is a distance D5.

Moreover, in the second embodiment, the main line ML1 has a straight line shape extending in the Y-axis direction, and thus the length of the entire balun 100A in the X-axis direction is reduced. As illustrated in the first and second embodiments, the degree of freedom in the design of the balun 100 can be increased by varying the shapes of the main line ML1 and sub-lines SL1 and SL2.

### Third Embodiment

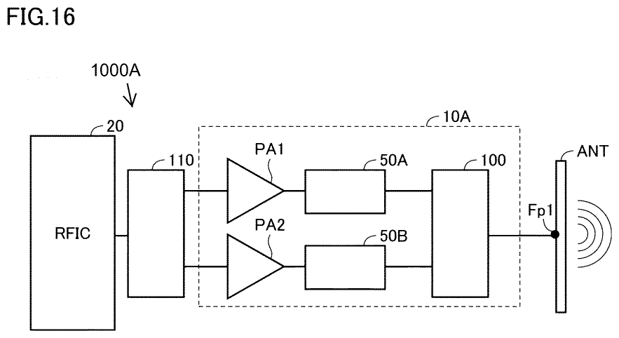

A schematic configuration of the balun 100 and a front-end circuit 10A according to a third embodiment will be described using FIG. 16. FIG. 16 is a schematic diagram of the configuration of a communication device 1000A according to the third embodiment. In the third embodiment, the description of substantially the same configuration as that of the first embodiment will not be repeated.

The communication device 1000A according to the third embodiment has a transformer 110 that includes an MCT device or a balun between the RFIC 20 and the front-end circuit 10A. The transformer 110 converts unbalanced signals to balanced signals and outputs the balanced signals to the front-end circuit 10A.

The front-end circuit 10A according to the third embodiment has power amplifiers PA1 and PA2 and matching circuits 50A and 50B. The power amplifiers PA1 and PA2 amplify the unbalanced signals converted by the transformer 110 and output the resulting signals to the matching circuits 50A and 50B in a respective manner.

The matching circuit 50A is provided between the power amplifier PA1 and the balun 100 and achieves impedance matching between the power amplifier PA1 and the balun 100. The matching circuit 50B is provided between the power amplifier PA2 and the balun 100 and achieves impedance matching between the power amplifier PA2 and the balun 100. In the third embodiment, unlike in the first embodiment, the balun 100 transforms balanced signals to unbalanced signals. The radio frequency signals obtained by the balun 100 according to the third embodiment converting balanced signals to unbalanced signals are transferred to the feed point Fp1 of the antenna ANT.

In this manner, the balun 100 according to the present embodiment can also be applied to baluns 100 that convert balanced signals to unbalanced signals. Even in the third embodiment, the provision of the lines CL1 to CL4 can improve the attenuation characteristics of the stopband while maintaining the pass characteristics of the desired passband.

### Fourth Embodiment

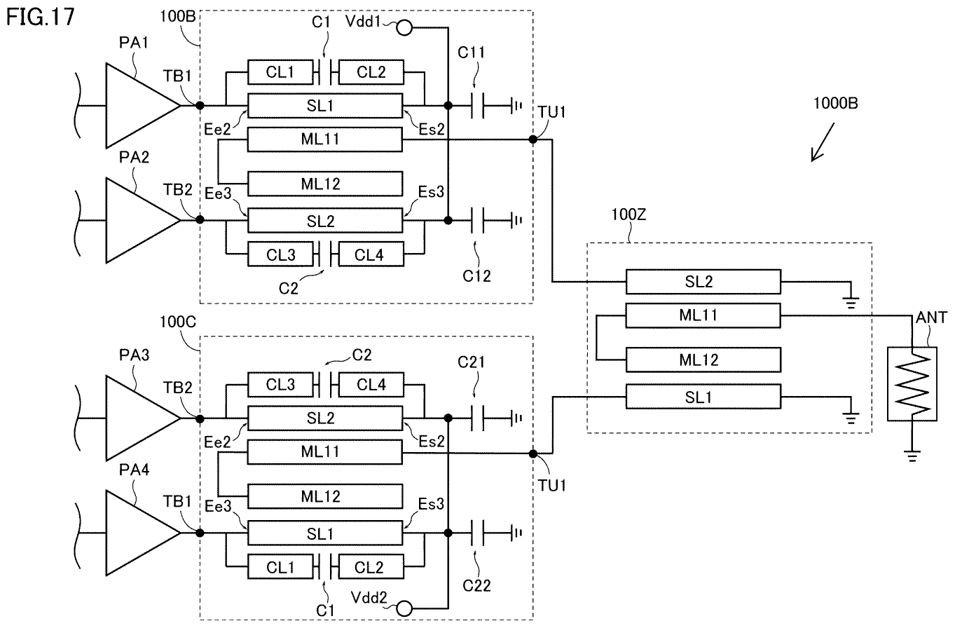

Schematic configurations of baluns 100B and 100C according to a fourth embodiment will be described using FIG. 17. FIG. 17 is a schematic diagram of the configuration of a communication device 1000B according to the fourth embodiment. In the third embodiment, the description of substantially the same configuration as that of the first embodiment will not be repeated.

The communication device 1000B according to the fourth embodiment has the baluns 100B and 100C according to the present embodiment and the balun 100Z according to the comparative example. The output terminal of the amplifier PA1 is connected to the balanced terminal TB1 of the balun 100B. The output terminal of the amplifier PA2 is connected to the balanced terminal TB2 of the balun 100B. The balun 100B converts the output signals from the amplifier PA1 and the amplifier PA2 to unbalanced signals and outputs the resulting signals from the unbalanced terminal TU1.

A power supply terminal Vdd1 is a terminal to which the power supply voltage supplied to the power amplifiers PA1 and PA2 from the outside is inputted. The power supply terminal Vdd1 is connected to the ground terminal with capacitors C11 and C12, which serve as bypass capacitors, interposed therebetween. The power supply voltage from the power supply terminal Vdd1 is supplied to the output terminal of the power amplifier PA1 via the sub-line SL1 of the balun 100B and to the output terminal of the power amplifier PA1 via the sub-line SL2 of the balun 100B. In this manner, the power supply terminal Vdd1 is connected to the end portion Es2 of the sub-line SL1 and the end portion Es3 of the sub-line SL2 in the balun 100B.

An output terminal of an amplifier PA4 is connected to the balanced terminal TB1 of the balun 100C. An output terminal of an amplifier PA3 is connected to the balanced terminal TB2 of the balun 100C. The balun 100C converts the output signals from the amplifier PA3 and the amplifier PA4 to unbalanced signals and outputs the resulting signals from the unbalanced terminal TU1.

A power supply terminal Vdd2 is a terminal to which the power supply voltage supplied to the power amplifiers PA3 and PA4 from the outside is inputted. The power supply terminal Vdd2 is connected to the ground terminal with capacitors C21 and C22, which serve as bypass capacitors, interposed therebetween. The power supply voltage from the power supply terminal Vdd2 is supplied to the output terminal of the power amplifier PA4 via the sub-line SL1 of the balun 100C and to the output terminal of the power amplifier PA3 via the sub-line SL2 of the balun 100C. In this manner, the power supply terminal Vdd2 is connected to the end portion Es2 of the sub-line SL1 and the end portion Es3 of the sub-line SL2 in the balun 100C.

The unbalanced terminal TU1 of the balun 100B is connected to one of the balanced terminals of the balun 100Z. The unbalanced terminal TU1 of the balun 100C is connected to the other one of the balanced terminals of the balun 100Z. The balun 100Z converts signals outputted from the unbalanced terminal TU1 of the balun 100B and signals outputted from the unbalanced terminal TU1 of the balun 100C to unbalanced terminals and outputs them to the antenna ANT.

In this manner, the communication device 1000B according to the fourth embodiment has the two baluns 100B and 100C. The resonant frequency of the LC series resonator formed by the capacitor C1 and the lines CL1 and CL2 in the balun 100B is the same value as that of the LC series resonator formed by the capacitor C1 and the lines CL1 and CL2 in the balun 100C. In addition, the resonant frequency of the LC series resonator formed by the capacitor C2 and the lines CL3 and CL4 in the balun 100B is the same value as that of the LC series resonator formed by the capacitor C2 and the lines CL3 and CL4 in the balun 100C. As a result, even in the baluns 100B and 100C according to the fourth embodiment, the provision of the lines CL1 to CL4 in each of the baluns 100B and 100C can improve the attenuation characteristics of the stopband while maintaining the pass characteristics of the desired passband.

### Fifth Embodiment

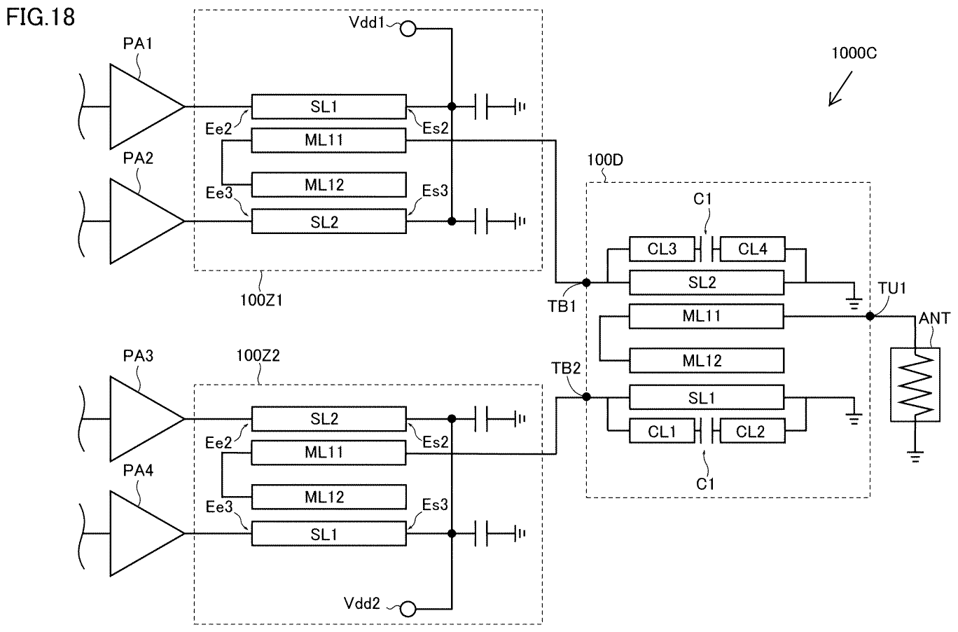

A schematic configuration of a balun 100D according to a fifth embodiment will be described using FIG. 18. FIG. 18 is a schematic diagram of the configuration of a communication device 1000C according to the fifth embodiment. In the fifth embodiment, the description of substantially the same configuration as those of the first and fourth embodiments will not be repeated.

As illustrated in FIG. 18, the communication device 1000C has baluns 100Z1 and 100Z2 according to a comparative example and the balun 100D according to the present embodiment. The balun 100Z1 converts balanced signals outputted from the power amplifiers PA1 and PA2 to unbalanced signals and outputs the resulting signals to the balanced terminal TB1 of the balun 100D. The balun 100Z2 converts balanced signals outputted from the power amplifiers PA3 and PA4 to unbalanced signals and outputs the resulting signals to the balanced terminal TB2 of the balun 100D. The balun 100D converts the signals inputted from the balanced terminals TB1 and TB2 to unbalanced signals and outputs the resulting signals to the antenna ANT.

Even in the fifth embodiment, the attenuation characteristics of the stopband can be improved while maintaining the pass characteristics of the desired passband by the balun 100D having the lines CL1 to CL4. In addition, the number of components can be reduced compared with that in the fourth embodiment, and the increase in cost can be suppressed in the fifth embodiment. Note that, in the example in FIG. 18, the power supply terminal Vdd1 is connected to the end portion Es2 of the sub-line SL1 and the end portion Es3 of the sub-line SL2 in the balun 100Z1 according to the comparative example. In a certain aspect, the power supply terminal Vdd1 may be connected to the end portion Ee2 of the sub-line SL1 and the end portion Ee3 of the sub-line SL2.

### Item 1

A balun comprising: a dielectric substrate; a ground electrode, an unbalanced terminal, and a pair of balanced terminals including a first balanced terminal that are provided in or on the dielectric substrate; a main line with one end connected to the unbalanced terminal and another end left open; a first sub-line with one end connected to the first balanced terminal and another end connected to the ground electrode; a first line with one end connected to the first balanced terminal and another end left open; and a second line with one end connected to the ground electrode and another end left open, wherein the first sub-line is arranged between the first line and the main line and between the second line and the main line, and the other end of the first line faces the other end of the second line.

### Item 2

The balun according to Item 1, wherein a length of the first line in its extending direction is equal to that of the second line in its extending direction.

### Item 3

The balun according to Item 1 or 2, wherein the main line has a shape wound around a winding axis when a main surface of the dielectric substrate is viewed in plan view.

### Item 4

The balun according to Item 3, wherein a shortest distance between the main line and the first sub-line is longer than a shortest distance between the first sub-line and the first line and a shortest distance between the first sub-line and the second line.

### Item 5

The balun according to Item 1 or 2, wherein the main line has a straight line shape when a main surface of the dielectric substrate is viewed in plan view.

### Item 6

The balun according to Item 5, wherein a shortest distance between the main line and the first sub-line, a shortest distance between the first sub-line and the first line, and a shortest distance between the first sub-line and the second line are equal in length.

### Item 7

The balun according to any one of Items 1 to 6, wherein the first sub-line is arranged along the main line between the first line and second line and the main line, and when a main surface of the dielectric substrate is viewed in plan view, a width of the first line and that of the second line are smaller than that of the first sub-line.

### Item 8

The balun according to any one of Items 1 to 7, wherein a base material of the dielectric substrate is a compound semiconductor.

### Item 9

The balun according to any one of Items 1 to 8, wherein the pair of balanced terminals includes a second balanced terminal provided in or on the dielectric substrate, the balun comprising: a second sub-line with one end connected to the second balanced terminal and another end connected to the ground electrode; a third line with one end connected to the second balanced terminal and another end left open; and a fourth line with one end connected to the ground electrode and another end left open, wherein the second sub-line is arranged between the third line and the main line and between the fourth line and the main line, and the other end of the third line faces the other end of the fourth line.

### Item 10

A front-end circuit comprising: the balun according to Item 9; and an amplifier connected to at least one of the first balanced terminal, the second balanced terminal, and the unbalanced terminal, wherein the amplifier is formed on the dielectric substrate.

### Item 11

The front-end circuit according to Item 10, further comprising: a power supply terminal to which power supplied to the amplifier is inputted, wherein the power supply terminal is connected to the other end of the first sub-line.

### Item 12

A balun in which a first frequency band is a passband and a second frequency band is an attenuation band, the balun comprising: a dielectric substrate; a ground electrode, an unbalanced terminal, and a pair of balanced terminals including a first balanced terminal that are provided in or on the dielectric substrate; a main line with one end connected to the unbalanced terminal and another end left open; a first sub-line with one end connected to the first balanced terminal and another end connected to the ground electrode; a first line with one end connected to the first balanced terminal and another end left open; a second line with one end connected to the ground electrode and another end left open; and a first capacitor connected between the other end of the first line and the other end of the second line, wherein a resonant frequency of an LC series resonator formed by the first capacitor, the first line, and the second line is a center frequency of the second frequency band, and a resonant frequency of an LC parallel resonator formed by the first capacitor and the first sub-line is a center frequency of the first frequency band.

### Item 13

The balun according to Item 12, wherein the first frequency band is a frequency band between 120 to 140 GHz.

### Item 14

The balun according to Item 12 or 13, wherein the second frequency band is a frequency band between 60 to 90 GHz.

### Item 15

The balun according to any one of Items 12 to 14, wherein the pair of balanced terminals includes a second balanced terminal provided in or on the dielectric substrate, the balun comprising: a second sub-line with one end connected to the second balanced terminal and another end connected to the ground electrode; a third line with one end connected to the second balanced terminal and another end left open; a fourth line with one end connected to the ground electrode and another end left open; and a second capacitor connected between the other end of the third line and the other end of the fourth line, wherein a resonant frequency of an LC series resonator formed by the second capacitor, the third line, and the fourth line is a center frequency of a third frequency band different from the second frequency band, and a resonant frequency of an LC parallel resonator formed by the second capacitor and the second sub-line is the center frequency of the first frequency band.

The embodiments disclosed herein should be considered illustrative and not restrictive in all aspects. The scope of the disclosure is indicated by the claims, not by the above description, and is intended to include all changes within the claims and the meaning and scope of equivalents.
ANT antenna
Ar1, Ar2 region
C1, C2, C11, C12, C21, C22 capacitor
CL, CL1 to CL4 line
Cm1 inter-line capacitance
Cp1, Rt1, Rt2 point
Cs1 to Cs3 line capacitance
D1, D2, D5, Dx1 distance
Ec1 to Ec4, Ee1 to Ee3, Es1 to Es3 end portion
Fp1, Fp2 feed point
Mk1 the ground electrode
LN1, LN1Z, LN2, LN3, Lx1, Ly1 line
Ly1D, Ly1U, Ly2U, Ly2D layer
ML1 main line
PA, PA1 to PA4 power amplifier
Pt1 to Pt3 wiring pattern
SL1, SL2 sub-line
Sb1 dielectric substrate
Sf1, Sf2 main surface
TB1, TB2 balanced terminal
TU1 unbalanced terminal
Vdd1, Vdd2 power supply terminal
W1, WM1 width

1. A balun comprising:
a dielectric substrate;
a ground electrode, an unbalanced terminal, and a pair of balanced terminals including a first balanced terminal that is in or on the dielectric substrate;
a main line having a first end connected to the unbalanced terminal and a second end that is open;
a first sub-line having a first end connected to the first balanced terminal and a second end connected to the ground electrode;
a first line having a first end connected to the first balanced terminal and a second end that is open; and
a second line having a first end connected to the ground electrode and a second end that is open,
wherein the first sub-line is between the first line and the main line, and between the second line and the main line, and
wherein the second end of the first line faces the second end of the second line.

2. The balun according to claim 1, wherein a length of the first line in its extending direction is equal to a length of the second line in its extending direction.

3. The balun according to claim 1, wherein the main line is wound around a winding axis when a main surface of the dielectric substrate is viewed in plan view.

4. The balun according to claim 3, wherein a shortest distance between the main line and the first sub-line is greater than a shortest distance between the first sub-line and the first line and is greater than a shortest distance between the first sub-line and the second line.

5. The balun according to claim 1, wherein the main line is a straight line when a main surface of the dielectric substrate is viewed in plan view.

6. The balun according to claim 5, wherein a shortest distance between the main line and the first sub-line, a shortest distance between the first sub-line and the first line, and a shortest distance between the first sub-line and the second line are equal in length.

7. The balun according to claim 1,
wherein the first sub-line is along the main line between the first line and second line, and the main line, and
wherein when a main surface of the dielectric substrate is viewed in plan view, a width of the first line and a width of the second line are less than a width of the first sub-line.

8. The balun according to claim 1, wherein a base material of the dielectric substrate is a compound semiconductor.

9. The balun according to claim 1,
wherein the pair of balanced terminals includes a second balanced terminal in or on the dielectric substrate,
wherein the balun comprises:
a second sub-line having a first end connected to the second balanced terminal and a second end connected to the ground electrode;
a third line having a first end connected to the second balanced terminal and a second end that is open; and
a fourth line having a first end connected to the ground electrode and a second end that is open,
wherein the second sub-line is between the third line and the main line, and between the fourth line and the main line, and
wherein the second end of the third line faces the second end of the fourth line.

10. A front-end circuit comprising:
the balun according to claim 9; and
an amplifier connected to at least one of the first balanced terminal, the second balanced terminal, or the unbalanced terminal,
wherein the amplifier is on the dielectric substrate.

11. The front-end circuit according to claim 10, further comprising:
a power supply terminal to which power supplied to the amplifier is input,
wherein the power supply terminal is connected to the second end of the first sub-line.

12. A balun in which a first frequency band is a passband and a second frequency band is an attenuation band, the balun comprising:
a dielectric substrate;
a ground electrode, an unbalanced terminal, and a pair of balanced terminals including a first balanced terminal that is in or on the dielectric substrate;
a main line having a first end connected to the unbalanced terminal and a second end that is open;
a first sub-line having a first end connected to the first balanced terminal and a second end connected to the ground electrode;
a first line having a first end connected to the first balanced terminal and a second end that is open;
a second line having a first end connected to the ground electrode and a second end that is open; and
a first capacitor connected between the second end of the first line and the second end of the second line,
wherein a resonant frequency of an LC series resonator comprising the first capacitor, the first line, and the second line is a center frequency of the second frequency band, and
wherein a resonant frequency of an LC parallel resonator comprising the first capacitor and the first sub-line is a center frequency of the first frequency band.

13. The balun according to claim 12, wherein the first frequency band is between 120 to 140 GHz.

14. The balun according to claim 12, wherein the second frequency band is between 60 to 90 GHz.

15. The balun according to claim 12,
wherein the pair of balanced terminals includes a second balanced terminal in or on the dielectric substrate,
wherein the balun comprises:
a second sub-line having a first end connected to the second balanced terminal and a second end connected to the ground electrode;
a third line having a first end connected to the second balanced terminal and a second end that is open;
a fourth line having a first end connected to the ground electrode and a second end that is open; and
a second capacitor connected between the second end of the third line and the second end of the fourth line,
wherein a resonant frequency of an LC series resonator comprising the second capacitor, the third line, and the fourth line is a center frequency of a third frequency band, the third frequency band being different from the second frequency band, and
wherein a resonant frequency of an LC parallel resonator comprising the second capacitor and the second sub-line is the center frequency of the first frequency band.
